(19) United States
(12) Patent Application Publication
(10) Pub. No.: US 2014/0254117 A1
(43) Pub. Date: Sep. 11, 2014

(54) ANISOTROPIC CONDUCTIVE FILM AND DISPLAY APPARATUS HAVING THE SAME

(71) Applicant: SAMSUNG DISPLAY CO., LTD., Yongin-City (KR)

(72) Inventors: Moon-Seok Roh, Yongin-City (KR); Sang-Urn Lim, Yongin-City (KR)

(73) Assignee: SAMSUNG DISPLAY CO., LTD., Yongin-City (KR)

(21) Appl. No.: 13/935,358

(22) Filed: Jul. 3, 2013

(30) Foreign Application Priority Data
Mar. 5, 2013 (KR) 10-2013-0023363

(51) Int. Cl. H05K 1/03; H05K 1/09

(52) U.S. Cl. CPC H05K 1/0353; H05K 1/09
USPC 361/760; 174/258; 174/257

(57) ABSTRACT

An anisotropic conductive film includes an insulating adhesive resin layer, and a plurality of conductive particles located at the insulating adhesive resin layer and comprising acutely angled edges.

### CROSS-REFERENCE TO RELATED APPLICATION

This application claims priority to and the benefit of Korean Patent Application No. 10-2013-0023363, filed on Mar. 5, 2013, in the Korean Intellectual Property Office, the entire content of which is incorporated herein by reference.

### BACKGROUND

1. Field

An aspect of embodiments of the present invention relates to an anisotropic conductive film and a display apparatus having the same.

2. Description of the Related Art

An anisotropic conductive film (ACF) is widely used as a material for electrically connecting an electric component, semiconductor, or a driver integrated circuit (IC) of a flat display apparatus such as a liquid crystal display (LCD), a plasma display panel device (PDP), and an organic light emitting display (OLED).

A display apparatus may include a display panel for displaying an image and a flexible circuit film for applying a control signal of a driver IC to the display panel. A flexible circuit film may be coupled to a display panel through a film on glass (FOG) mount method in consideration of reducing cost and having a possibility of mounting. According to the FOG mount method, an anisotropic conductive film is between the flexible circuit film and the display panel, and then is pressed at a high temperature so that the flexible circuit film and the display panel are electrically connected to each other.

### SUMMARY

One or more embodiments of the present invention provide an anisotropic conductive film having an increased (or improved) electric conductivity, and a display apparatus having the same.

An embodiment of the present invention provides an anisotropic conductive film including an insulating adhesive resin layer, and a plurality of conductive particles located at the insulating adhesive resin layer and comprising acutely angled edges.

The conductive particles may be cone-shaped or pyramid-shaped.

The respective side surfaces of the conductive particles that are adjacent the edges of the conductive particles may be acutely angled with each other.

The conductive particles may include an insulation core, and a conductive film surrounding the insulation core.

The insulation core may include at least one of a polypropylene or silica.

The conductive film may include any one selected from the group consisting of nickel, gold, palladium, and combinations thereof.

A hardness of the insulation core may be stronger than that of the conductive film.

A display apparatus according to another exemplary embodiment of the present invention includes: a display panel including a pad configured to input and output electrical signals, a driver configured to drive the display panel, and a conductive adhesive layer between the pad and the driver to electrically couple the display panel and the driver, the conductive adhesive layer including an adhesive resin layer and a plurality of conductive particles having acutely angled edges.

The conductive adhesive layer may include an anisotropic conductive film.

The driver may include a flexible circuit film including a driving chip.

The display panel may further include a thin film substrate formed of at least one material selected from the group consisting of polyethyleneterephthalate (PET), polycarbonate (PC), acryl, polymethylmethacrylate (PMMA), triacetylcellulose (TAC), polyethersulfone (PES), polyimide (PI), and combinations thereof.

### BRIEF DESCRIPTION OF THE DRAWINGS

Example embodiments of the present invention will now be described more fully hereinafter with reference to the accompanying drawings; however, they may be embodied in different forms, and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it may be the only element between the two elements, or one or more intervening elements may also be present. Like reference numerals refer to like elements throughout.

FIG. 1 is a partial cross-sectional view schematically showing a display apparatus having an anisotropic conductive film according to an exemplary embodiment of the present invention.

FIG. 2 is a schematic cross-sectional view showing the anisotropic conductive film shown in FIG. 1;

FIG. 3 is a cross-sectional view of a conductive particle shown in FIG. 2; and

FIGS. 4A to 4C are views showing examples of a conductive particle of embodiments of the present invention.

### DETAILED DESCRIPTION

Hereinafter, exemplary embodiments will be described in detail with reference to the accompanying drawings.

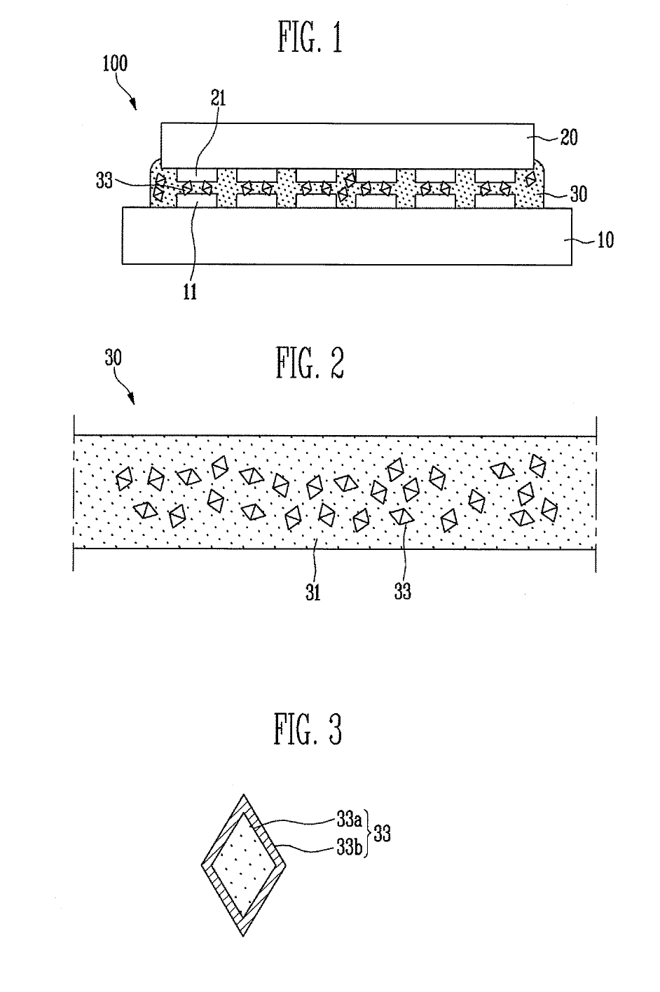

FIG. 1 is a partial cross-sectional view schematically showing a display apparatus having an anisotropic conductive film according to an exemplary embodiment of the present invention. FIG. 2 is a schematic cross-sectional view showing the anisotropic conductive film shown in FIG. 1.

Referring FIG. 1, a display apparatus 100 according to an exemplary embodiment includes a display panel, a driving unit (or a driver) for controlling driving of the display panel, and a conductive adhesive layer electrically coupled to the display panel and the driving unit.

The display panel includes a display substrate 10 divided into a display area for displaying an image, and a non-display area.

The non-display area is an area where visibility may be reduced (or prevented) using a black matrix, or the like, and serves to hide a wire pattern and a driving circuit coupled to pixels in the display area.

The display apparatus may be a liquid crystal display, a field emission display, a plasma display panel, an organic light emitting display device, or the like. The display substrate 10 may be an array substrate of these display apparatus.

Here, the display substrate 10 may be a material having a transparency, a high heat resistance, and a chemical resistance, and may be a thin film substrate formed of at least one material selected from a group of polyethyleneterephthalate (PET), polycarbonate (PC), acryl, polymethylmethacrylate (PMMA), triacetylcellulose (TAC), polyethersulfone (PES) and/or polyimide (PI).

The display substrate 10 may include a pad unit (or pad) 11 for coupling to an external driving circuit. In embodiments of the present invention, the pad unit 11 is configured to include a conductive material to receive an electric signal, such as a control signal, and is coupled to a bump unit 21 of a flexible circuit film 20, as described below.

The driving unit may include the flexible circuit film 20 on which a driving chip is mounted. The driving chip generates driving signals to drive the display panel by reacting with various control signals applied through the flexible circuit film 20. The driving signal generated from the driving chip is applied to a gate line and to a data line of the display substrate 10, and drives the display panel.

The flexible circuit film 20 is electrically coupled to the display substrate 10 through the conductive adhesive layer. The flexible circuit film 20 receives an external control signal to control driving of the display panel, and then applies the signal to the display panel. In addition, the flexible circuit film 20 may include a driving circuit unit that generates various control signals.

A bump unit 21 is positioned (or located) on the flexible circuit film 20 to face the pad unit 11 of the display substrate 10. The bump unit 21 is electrically coupled to the pad unit 11 of the display panel 10 through the conductive adhesive layer. The bump unit 21 may be configured of (or formed of) a conductive material to transmit the control signal.

The conductive adhesive layer is positioned (or located) between the display substrate 10 and the flexible circuit film 20. As a conductive adhesive layer, an anisotropic conductive film (ACF) may be used.

A coupling by using the anisotropic conductive film 30 may be implemented by performing a preliminary pressing process, which attaches (or couples) the anisotropic conductive film 30 to the display panel, and by performing a primary pressing process, which bonds the display panel with the flexible circuit film 20.

Referring to FIG. 2, the anisotropic conductive film 30 includes an adhesive resin layer 31 and multiple conductive particles 33 having acute edges.

The adhesive resin layer 31 may be stably maintained at room temperature without reaction, and may include a thermosetting resin, which is cured by heat, and the structure of the thermosetting resin may be densified. Accordingly, at the time of performing a heat pressing process, the display substrate 10 and the flexible circuit film 20 are bonded with each other.

For example, the adhesive resin layer 31 may include a thermosetting resin, such as epoxy resin. Because the adhesive resin layer 31 may be configured of (or formed of) an insulation material, it may insulate an adjacent pad unit 11 or an adjacent bump unit 21.

The conductive particles, which serve to electrically couple the display substrate 10 and the flexible circuit film 20, may be irregularly distributed at/in the adhesive resin layer 31 of the anisotropic conductive film 30.

A mounting of the flexible circuit film 20 may be implemented by thermo-compression of the anisotropic conductive film 30, which is located between the display substrate 10 and the flexible circuit film 20, the thermo-compression being in a vertical direction of (or an orthogonal direction to) the display substrate 10 and the flexible circuit film 20 of the display panel.

Here, the pad unit 11 and the bump unit 21 may be electrically coupled due to contact areas of the pad unit 11 and the bump unit 21 contacting respective end parts of the conductive particles 33 between the pad unit 11 and the bump unit 21.

Here, the conductive particles 33 include acute edges pointing in different directions from each other to increase (or improve) infiltration, and to increase/improve electrical contact with the contact areas.

The conductive particles 33 other than those at the contact area are suspended in (or deposited at) the adhesive resin layer 31 by compression, and are moved to a vicinity of a coupling area of the display substrate 10 and the flexible circuit film 20. In some exemplary embodiments of the present invention, the conductive particles 33 have an electric charge and have a same polarity as each other, so that a repulsive force, which causes the conductive particles 33 to push against each other, is generated. Accordingly, a lumping (or aggregating) phenomenon of the conductive particles 33 may be reduced (or prevented).

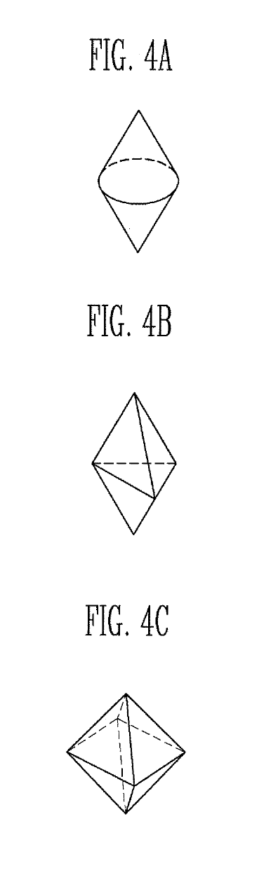

FIG. 3 is a cross-sectional view of a conductive particle shown in FIG. 2; and FIGS. 4A to 4C are views showing examples of a conductive particle of embodiments of the present invention.

Referring to FIG. 3, the conductive particles 33 according to an exemplary embodiment of the present invention may include an insulation material core 33a, and a conductive material conductive film 33b that surrounds (or encompasses) the core 33a therein.

The core 33a may have an intensity (or hardness) stronger than that of the pad unit 11 and the bump unit 21 forming the contact area and of the conductive film 33b along the peripheral part of the core 33a. Therefore, the likelihood of penetration of the core 33a through the conductive film 33b near the contact area of the conductive particles 33 may be increased. However, the conductive film 33b of the conductive particles 33 of the present embodiment may be capable of reducing (or preventing) damage to itself when compression occurs. For example, the core 33a may include any one of a polypropylene and silica.

In another exemplary embodiment of the present invention, the core 33a has an elasticity (e.g., a predetermined elasticity) so that contact between the pad unit 11 and the bump unit 21 is maintained, and thus the electrical contact state therein is continuously maintained, by virtue of the elasticity (e.g., the predetermined elasticity) when the conductive particles 33 are crushed. For example, the core 33a may be formed of an acryl based resin.

The conductive film 33b electrically couples the display substrate 10 to the flexible circuit film 20. The conductive film 33b may be formed of a metal material capable of transferring electric signals. For example, the conductive film 33b may be configured (or formed) of gold (Au) which is a low resistance metal, or of a double layer of nickel (Ni) and gold (Au). In addition, the conductive film 33b may be configured of (or formed of) a structure in which nickel (Ni) surrounds (or encompasses) the outside of the core 33a, and in which the outside of the nickel (Ni) may be coated with gold (Au).

Referring to FIG. 4A to 4C, the conductive particles 33 may have various shapes. For example, the conductive particles 33 may be a circular cone shape, a triangle pyramid shape, or a rectangle pyramid shape. The conductive particles 33 may entirely have adhesion properties in which flat surfaces of the circular cone or the pyramid are adhesive to each other. Here, the acute edges of the circular cone and the pyramid are located in opposite directions to each other.

The acute edges of the conductive particles 33 may be sharply processed or grinded, such as by a gimlet, so that the side surfaces of the conductive particles 33 form acute angles in order to increase electrical contact. However, the shapes of the conductive particles 33 are not limited to simply a concave-convex or a step structure.

However, in consideration of the very small size of the conductive particles 33, for example, they may be about 3 μm to about 10 μm, the sharpened degree of the edge and the thickness and the angles of the side surfaces may be determined by experiment and by statistics, so as not to damage the edges when compression occurs.

By way of summation and review, in embodiments of the present invention, the anisotropic conductive film is configured with an adhesive resin layer and conductive particles unevenly distributed in the adhesive resin layer. The adhesive resin layer serves to physically couple the flexible circuit film to the display panel, and the conductive particles of the adhesive resin layer serve to electrically couple the flexible circuit film and the display panel to each other.

Here, electric conductivity of an anisotropic conductive film located between the display panel and the flexible circuit film may be in proportion to the number of contact areas coupled to a contact region of both sides.

However, a conductive particle in the related art having a round ball shape may not have as high electric conductivity as the contact area with a smaller adhesive object. Further, when the adhesive object is made of a material that is flexible and soft, pressure at the time of adhesion may not sufficiently be supplied such that partial non-contact may be generated.

As set forth above, according to embodiments of the present invention, infiltration characteristics and contact to the contact area are increased (or improved), as a result, electric conductivity may be increased (or improved) and reliability can be increased (or secured) by using the anisotropic conductive film having a plurality of the conductive particles having acute edges.

Example embodiments of the present invention have been disclosed herein, and although specific terms are employed, they are used in, and are to be interpreted in, a generic and descriptive sense only, and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments, unless otherwise specifically indicated. Accordingly, it will be understood by those of skill in the art that various changes in form and details may be made without departing from the spirit and scope of the present invention as set forth in the following claims, and equivalents thereof.

What is claimed is:

1. An anisotropic conductive film comprising:
an insulating adhesive resin layer; and
a plurality of conductive particles located at the insulating adhesive resin layer and comprising acutely angled edges.

2. The anisotropic conductive film according to claim 1, wherein the conductive particles are cone-shaped or pyramid-shaped.

3. The anisotropic conductive film according to claim 1, wherein respective side surfaces of the conductive particles that are adjacent the edges of the conductive particles are acutely angled with each other.

4. The anisotropic conductive film according to claim 1, wherein the conductive particles comprise an insulation core, and a conductive film surrounding the insulation core.

5. The anisotropic conductive film according to claim 4, wherein the insulation core comprises at least one of a polypropylene or silica.

6. The anisotropic conductive film according to claim 4, wherein the conductive film comprises any one selected from the group consisting of nickel, gold, palladium, and combinations thereof.

7. The anisotropic conductive film according to claim 4, wherein a hardness of the insulation core is stronger than that of the conductive film.

8. A display apparatus comprising,
a display panel comprising a pad configured to input and output electrical signals;
a driver configured to drive the display panel; and
a conductive adhesive layer between the pad and the driver to electrically couple the display panel and the driver, the conductive adhesive layer comprising an adhesive resin layer and a plurality of conductive particles having acutely angled edges.

9. The display apparatus according to claim 8, wherein the conductive adhesive layer comprises an anisotropic conductive film.

10. The display apparatus according to claim 8, wherein the driver comprises a flexible circuit film comprising a driving chip.

11. The display apparatus according to claim 8, wherein the display panel further comprises a thin film substrate comprising at least one material selected from the group consisting of polyethyleneterephthalate (PET), polycarbonate (PC), acryl, polymethylmethacrylate (PMMA), triacetylcellulose (TAC), polyethersulfone (PES), polyimide (PI), and combinations thereof.
